(19) United States
(12) Patent Application Publication
(10) Pub. No.: US 2022/0039279 A1
(43) Pub. Date: Feb. 3, 2022

(54) CONFIGURABLE CARD RETENTION FOR RISERS

(71) Applicant: Dell Products L.P., Round Rock, TX (US)

(72) Inventor: Julian Yu-Hao CHEN, Austin, TX (US)

(73) Assignee: Dell Products L.P., Round Rock, TX (US)

(21) Appl. No.: 16/983,162

(22) Filed: Aug. 3, 2020

(51) Int. Cl. H05K 5/02; H05K 5/03; H05K 7/14

(52) U.S. Cl. CPC H05K 5/0295; H05K 7/1417; H05K 5/03; H05K 5/0221

(57) ABSTRACT

A mechanical retention assembly for use with an information handling resource may include a body configured to mechanically couple to a riser card, a bracket mechanically coupled to the body and configured to mechanically retain respective tails of component cards received into the riser card, and at least one low-profile retention feature rotatably coupled to the body and configured to be movable between an open position and a closed position relative to the body. In the open position, the at least one low-profile retention feature may allow for insertion and removal of a component card into a connector of the riser card associated with the at least one low-profile retention feature. In the closed position, the at least one low-profile retention feature may mechanically retain a top edge of a low-profile component card received into the riser card.

### TECHNICAL FIELD

The present disclosure relates in general to information handling systems, and more particularly to systems and methods for providing a configurable card retention mechanism for components installed on a riser in an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Increasingly, information handling systems are making use of low-profile components, such as low-profile Peripheral Component Interconnect Express (PCIe) devices, instead of larger “full-height” devices. Such low-profile components may render such components capable of accepting lower cooling airflow requirements relative to their full-height counterparts while still maintaining thermal capabilities. However, by making the form factor of such devices smaller, such devices have also become heavier due to increased densities and increased sizes of heatsinks thermally coupled to the devices. In turn, it is increasingly difficult to retain the printed circuit board cards used to implement such devices, and accordingly, these cards are harder to retain in place (e.g., remain mechanically and electrically coupled to a riser card), in response to mechanical shock and vibrations to the information handling system in which the card is disposed. While some retention mechanisms have been developed, such mechanisms render it difficult for a user to easily insert and remove a card.

### SUMMARY

In accordance with the teachings of the present disclosure, the disadvantages and problems associated with existing approaches to disposing information handling system components within an information handling system may be reduced or eliminated.

In accordance with embodiments of the present disclosure, a mechanical retention assembly for use with an information handling resource may include a body configured to mechanically couple to a riser card, a bracket mechanically coupled to the body and configured to mechanically retain respective tails of component cards received into the riser card, and at least one low-profile retention feature rotatably coupled to the body and configured to be movable between an open position and a closed position relative to the body. In the open position, the at least one low-profile retention feature may allow for insertion and removal of a component card into a connector of the riser card associated with the at least one low-profile retention feature. In the closed position, the at least one low-profile retention feature may mechanically retain a top edge of a low-profile component card received into the riser card.

In accordance with these and other embodiments of the present disclosure, an information handling system may include a riser card and mechanical retention assembly for use with an information handling resource. The mechanical retention assembly may include a body configured to mechanically couple to the riser card, a bracket mechanically coupled to the body and configured to mechanically retain respective tails of component cards received into the riser card, and at least one low-profile retention feature rotatably coupled to the body and configured to be movable between an open position and a closed position relative to the body. In the open position, the at least one low-profile retention feature may allow for insertion and removal of a component card into a connector of the riser card associated with the at least one low-profile retention feature. In the closed position, the at least one low-profile retention feature may mechanically retain a top edge of a low-profile component card received into the riser card.

In accordance with these and other embodiments of the present disclosure, a method may include mechanically coupling a bracket to a body configured to mechanically couple to a riser card such that the bracket is configured to mechanically retain respective tails of component cards received into the riser card and rotatably coupling at least one low-profile retention feature to the body such that the at least one low-profile retention feature is configured to be movable between an open position and a closed position relative to the body. In the open position, the at least one low-profile retention feature may allow for insertion and removal of a component card into a connector of the riser card associated with the at least one low-profile retention feature. In the closed position, the at least one low-profile retention feature may mechanically retain a top edge of a low-profile component card received into the riser card.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an isometric perspective view of an example information handling system, in accordance with embodiments of the present disclosure;

FIGS. 2A and 2B each illustrate side elevation views of an example configurable mechanical retention assembly to support standard-sized component cards on a riser card, in accordance with embodiments of the present disclosure;

FIGS. 3A and 3B each illustrate side elevation views of another example configurable mechanical retention assembly to support standard-sized component cards on a riser card, in accordance with embodiments of the present disclosure;

FIG. 4 illustrates an isometric view showing detail of removable tail brackets and their respective low-profile retention features, in accordance with embodiments of the present disclosure; and

FIG. 5 illustrates a side elevation view of an example configurable mechanical retention assembly, in accordance with embodiments of the present disclosure.

### DETAILED DESCRIPTION

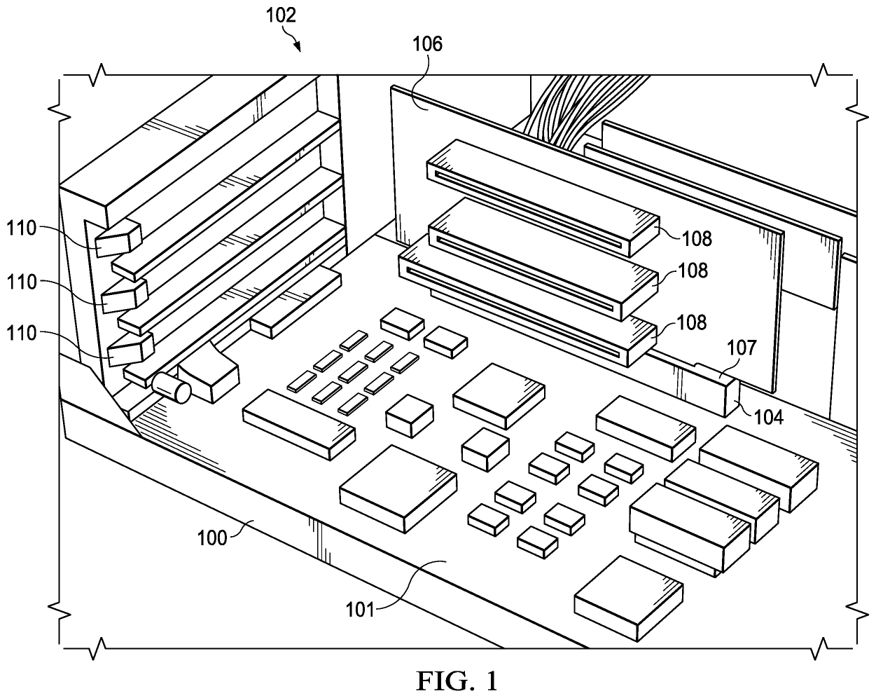

Preferred embodiments and their advantages are best understood by reference to FIGS. 1 through 5, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, power supplies, air movers (e.g., fans and blowers) and/or any other components and/or elements of an information handling system.

FIG. 1 illustrates an isometric perspective view of an example information handling system 102, in accordance with embodiments of the present disclosure. As depicted, information handling system 102 may include a chassis 100, a motherboard 101, a riser card 106 mechanically and communicatively coupled to motherboard 101, and one or more other information handling resources.

Chassis 100 may be an enclosure that serves as a container for various information handling resources, and may be constructed from steel, aluminum, plastic, and/or any other suitable material. Although the term “chassis” is used, chassis 100 may also be referred to as a sled, case, cabinet, tower, box, enclosure, and/or housing.

Motherboard 101 may include a circuit board mechanically coupled to chassis 100 (e.g., via screws, fasteners, and/or any other mechanical mechanism) and configured to provide structural support for one or more information handling resources of information handling system 102 and/or electrically couple one or more of such information handling resources to each other and/or to other electric or electronic components external to information handling system 102. For example, motherboard 101 may include one or more processors, one or more memories, and one or more other information handling resources. As a specific example, motherboard 101 may have mounted thereon a receptacle connector 104 having mechanical features (e.g., a rigid plastic bracket) and electrically-conductive features (e.g., pins) for receiving a corresponding edge connector (e.g., edge connector 107 of riser card 106), thus electrically coupling electrically conductive traces (e.g., pins) of the edge connector to corresponding electrically-conductive features of receptacle connector 104 and mechanically coupling an information handling resource (e.g., riser card 106) to receptacle connector 104 in order to maintain such electrical coupling such that the information handling resource is electrically and communicatively coupled to motherboard 101.

Riser card 106 may comprise a printed circuit board configured to receive a multitude of signal lines (e.g., bused signal lines) via a single connector (e.g., edge connector 107) from motherboard 101 and distribute such signals lines via dedicated connectors (e.g., receptacle connectors 108) mounted on riser card 106. Thus, riser card 106 may enable the addition of expansion cards (e.g., PCIe cards), particularly where a height of chassis 100 does not allow for a perpendicular placement of expansion cards. As shown in FIG. 1, riser card 106 may plug into motherboard 101 (e.g., via edge connector 107) and may provide additional slots, via receptacle connector 108 mounted to riser card 106, for one or more other information handling resources (e.g., PCIe and/or other adapter cards). Accordingly, each receptacle connector 108 may be configured to receive a corresponding edge connector of an information handling resource (e.g., PCIe and/or other adapter card). Consequently, riser card 106 may enable coupling of additional information handling resources in an orientation parallel to motherboard 101, which may save space within chassis 100.

As also depicted in FIG. 1, chassis 100 may comprise one or more card retention features 110 (e.g., latches, mechanical loading features, etc.) each configured to mechanically engage with an information handling resource disposed in a receptacle connector 108 of riser card 106 in order to assist (e.g., along with the receptacle connector 108) in mechanically constraining movement of such information handling resource, in order to ensure proper electrical coupling of such information handling resource to motherboard 101.

In addition to motherboard 101 and riser card 106, information handling system 102 may include one or more other information handling resources.

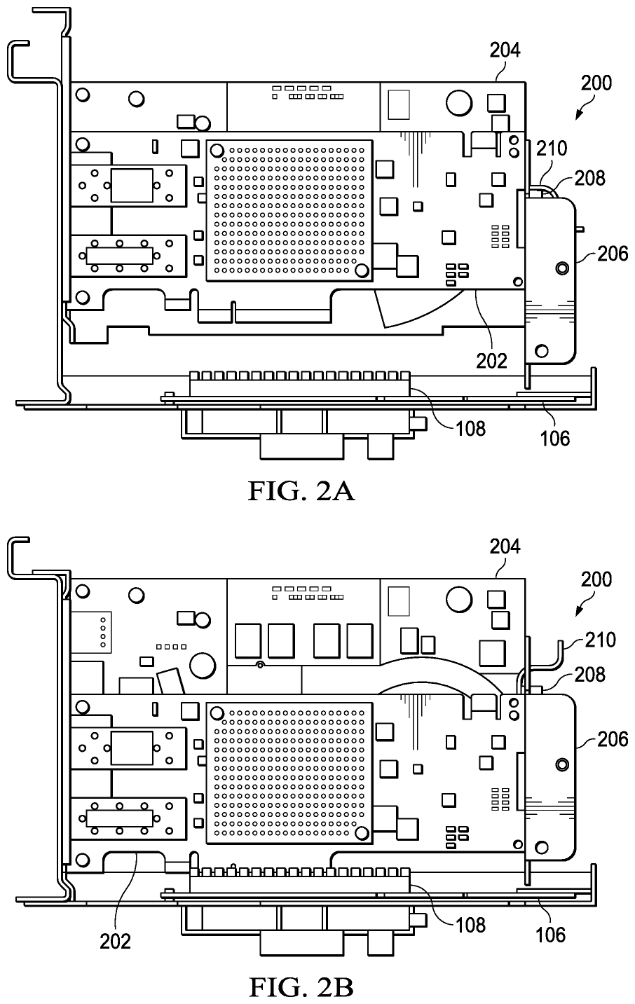

FIGS. 2A and 2B each illustrate side elevation views of an example configurable mechanical retention assembly 200 to support standard-sized component cards (e.g., Peripheral Component Interconnect Express or PCIe cards) on a riser card 106, in accordance with embodiments of the present disclosure. FIG. 2A illustrates a half-length, low-profile card 202 prior to insertion into a receptacle connector 108 of riser card 106 with a half-length, full-height card 204 already inserted in another receptacle connector 108 of riser card 106. FIG. 2B illustrates half-length, low-profile card 202 inserted into connector 108 of riser card 106 and half-length, full-height card 204 already inserted in another receptacle connector 108 of riser card 106.

As shown in FIGS. 2A and 2B, half-length, low-profile card 202 and half-length, full-height card 204 may be retained at their head ends (e.g., on the left end of each card 202, 204 as shown in FIGS. 2A and 2B) by features of chassis 100. Further, half-length, low-profile card 202 and half-length, full-height card 204 may be retained at their bottom edges due to the mating of edge connectors interfacing with corresponding receptacle connectors 108 of riser card 106.

As shown in FIGS. 2A and 2B, mechanical retention assembly 200 may include a body 206 mechanically coupled to riser card 106. Body 206 may be constructed from aluminum or other suitable material. Mechanical retention assembly 200 may also include one or more tail brackets 208 mechanically coupled to and extending from body 206 and configured to mechanically retain tail ends of half-length, low-profile card 202 and half-length, full-height card 204 (e.g., on the right end of each card 202, 204 as shown in FIGS. 2A and 2B). Tail brackets 208 may be constructed from plastic or other suitable material.

Also as shown in FIGS. 2A and 2B, mechanical retention assembly 200 may also include one or more low-profile retention features 210 rotatably coupled to body 206. During insertion and removal of half-length, low-profile card 202, a low-profile retention feature 210 associated with half-length, low-profile card 202 may be rotated into a first position relative to body 206, as shown in FIG. 2A, to allow for such insertion and removal. While half-length, low-profile card 202 is fully-inserted into its corresponding connector 108, low-profile retention feature 210 may be rotated into a second position relative to body 206, as shown in FIG. 2B, to provide mechanical retention of a top edge of half-length, low-profile card 202 (e.g., the edge of half-length, low-profile card 202 opposite of its bottom edge comprising its edge connector).

Although not shown in FIGS. 2A and 2B, a top edge of half-length, full-profile card 204 may be retained by features of chassis 100 (e.g., card retention features 110 of chassis 100 as shown in FIG. 1).

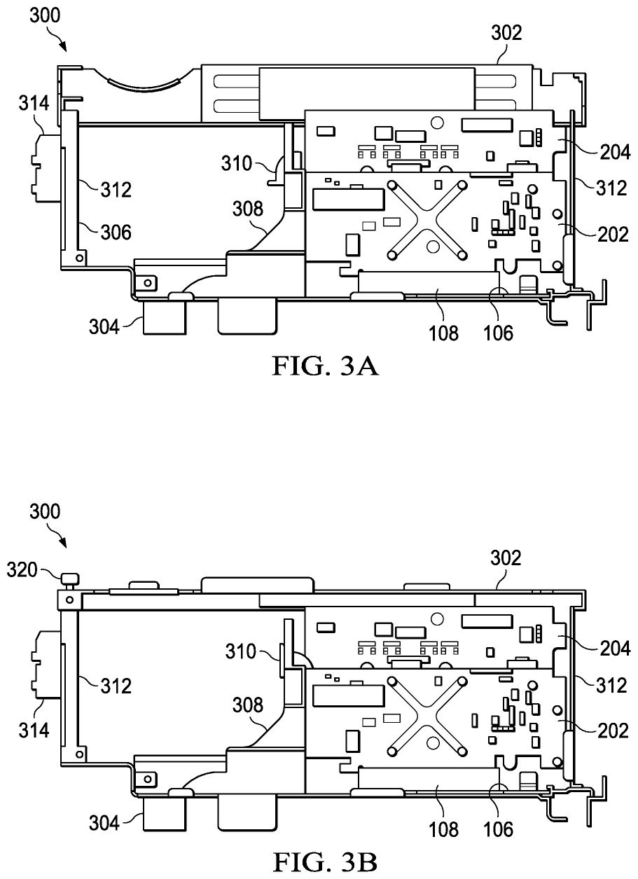

FIGS. 3A and 3B each illustrate side elevation views of an example configurable mechanical retention assembly 300 to support standard-sized component cards (e.g., PCIe cards) on a riser card 106, in accordance with embodiments of the present disclosure. FIG. 3A illustrates mechanical retention assembly 300 with a rotating riser cover 302 in an open position while FIG. 3B illustrates mechanical retention assembly 300 with rotating riser cover 302 in a closed position.

As shown in FIGS. 3A and 3B, half-length, low-profile card 202 and half-length, full-height card 204 may be retained at their head ends (e.g., on the right end of each card 202, 204 as shown in FIGS. 3A and 3B) by features of chassis 100. Further, half-length, low-profile card 202 and half-length, full-height card 204 may be retained at their bottom edges due to the mating of edge connectors interfacing with corresponding receptacle connectors 108 of riser card 106.

Further as shown in FIGS. 3A and 3B, mechanical retention assembly 300 may include a base 304 mechanically coupled to riser card 106 with opposite upright flanges 312 extending perpendicularly from base 304. Riser cover 302 may be rotabably coupled to upright flanges 312 to allow riser cover 302 to move between its open position and closed position. Further, riser cover 302 may include a feature 320 (e.g., a thumb screw) configured to mechanically interact with a corresponding feature of an upright flange 312 in order to maintain riser cover 302 in its closed position.

Also as shown in FIG. 3A, riser cover 302 may be placed in its open position to allow for removal and insertion of cards 202 and 204. In its closed position, riser cover 302 may retain half-length, full-profile card 204 at its top edge in order to maintain half-length, full-profile card 204 in its respective connector 108.

Mechanical retention assembly 300 may also include one or more removable tail brackets 308 configured to mechanically couple to and extending from base 304 and configured to mechanically retain tail ends of half-length, low-profile card 202 and half-length, full-height card 204 (e.g., on the left end of each card 202, 204 as shown in FIGS. 3A and 3B). Tail brackets 308 may be constructed from plastic or other suitable material.

Further as shown in FIGS. 3A and 3B, each removable tail bracket 308 may also include a low-profile retention feature 310 rotatably coupled to such removable tail bracket 308. During insertion and removal of half-length, low-profile card 202, a low-profile retention feature 310 associated with half-length, low-profile card 202 may be rotated into a first position relative to removable tail bracket 308, as shown in FIG. 3A, to allow for such insertion and removal. While half-length, low-profile card 202 is fully-inserted into its corresponding receptacle connector 108, low-profile retention feature 310 may be rotated into a second position relative to removable tail bracket 308, as shown in FIG. 3B, to provide mechanical retention of a top edge of half-length, low-profile card 202 (e.g., the edge of half-length, low-profile card 202 opposite of its bottom edge comprising its edge connector).

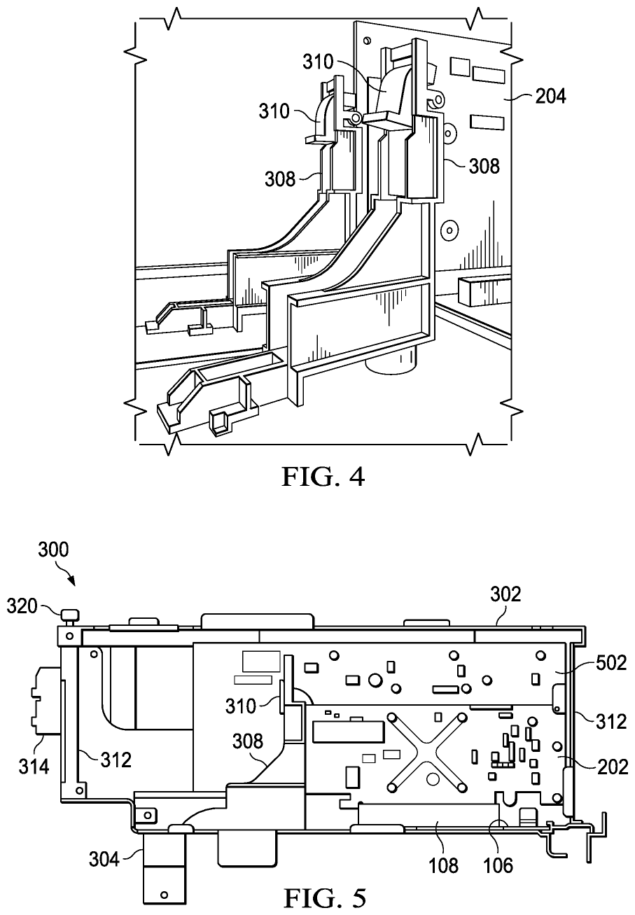

FIG. 4 illustrates an isometric view showing detail of removable tail brackets 308 and their respective low-profile retention features 310, in accordance with embodiments of the present disclosure.

FIG. 5 illustrates a side elevation view of example configurable mechanical retention assembly 300 supporting half-length, low-profile card 202, and full-length, full-profile card 502 on riser card 106, in accordance with embodiments of the present disclosure. As shown in FIG. 5, with the presence of full-length, full-profile card 502 on riser card 106, a removable tail bracket 308 may remain in place within mechanical retention assembly 300 to retain half-length, low-profile card 202. However, the removable tail bracket 308 associated with the connector 108 to which full-length, full-profile card 502 is inserted may be removed to allow full-length, full-profile card 502 to extend the full length between upright flanges 312. In its closed position, riser cover 302 may retain full-length, full-profile card 502 at its top edge. Further, an upright flange 312 may also include one or more tail brackets 314 mechanically coupled to and extending from such upright flange and configured to mechanically retain a tail end of full-length, full-profile card 502 (e.g., on the right end of card 502 as shown in FIG. 5). Tail brackets 314 may be constructed from plastic or other suitable material.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A mechanical retention assembly for use with an information handling resource, comprising:
a body configured to mechanically couple to a riser card;
a bracket mechanically coupled to the body and configured to mechanically retain respective tails of component cards received into the riser card; and
at least one low-profile retention feature rotatably coupled to the body and configured to be movable between an open position and a closed position relative to the body, wherein:
in the open position, the at least one low-profile retention feature allows for insertion and removal of a component card into a connector of the riser card associated with the at least one low-profile retention feature; and
in the closed position, the at least one low-profile retention feature mechanically retains a top edge of a low-profile component card received into the riser card.

2. The mechanical retention assembly of claim 1, wherein the bracket is removable from the body.

3. The mechanical retention assembly of claim 2, wherein the at least one low-profile retention feature is mechanically coupled to the bracket.

4. The mechanical retention assembly of claim 2, wherein the bracket is configured to mechanically retain respective tails of half-length component cards received into the riser card.

5. The mechanical retention assembly of claim 4, wherein removal of the bracket allows for insertion of a full-length component into a connector of the riser card corresponding to the removed bracket.

6. The mechanical retention assembly of claim 1, comprising a rotating riser cover rotatably coupled to the body and configured to be movable between an open position and a closed position relative to the body, wherein:
in the open position, the rotating riser cover allows for insertion and removal of component cards into the riser card; and
in the closed position, the rotating riser cover mechanically retains a top edge of a full-height component card received into the riser card.

7. An information handling system comprising:
a riser card; and
mechanical retention assembly for use with an information handling resource, comprising:
a body configured to mechanically couple to the riser card;
a bracket mechanically coupled to the body and configured to mechanically retain respective tails of component cards received into the riser card; and
at least one low-profile retention feature rotatably coupled to the body and configured to be movable between an open position and a closed position relative to the body, wherein:
in the open position, the at least one low-profile retention feature allows for insertion and removal of a component card into a connector of the riser card associated with the at least one low-profile retention feature; and
in the closed position, the at least one low-profile retention feature mechanically retains a top edge of a low-profile component card received into the riser card.

8. The information handling system of claim 7, wherein the bracket is removable from the body.

9. The information handling system of claim 8, wherein the at least one low-profile retention feature is mechanically coupled to the bracket.

10. The information handling system of claim 8, wherein the bracket is configured to mechanically retain respective tails of half-length component cards received into the riser card.

11. The information handling system of claim 10, wherein removal of the bracket allows for insertion of a full-length component into a connector of the riser card corresponding to the removed bracket.

12. The information handling system of claim 7, comprising a rotating riser cover rotatably coupled to the body and configured to be movable between an open position and a closed position relative to the body, wherein:
in the open position, the rotating riser cover allows for insertion and removal of component cards into the riser card; and
in the closed position, the rotating riser cover mechanically retains a top edge of a full-height component card received into the riser card.

13. A method comprising:
mechanically coupling a bracket to a body configured to mechanically couple to a riser card such that the bracket is configured to mechanically retain respective tails of component cards received into the riser card; and
rotatably coupling at least one low-profile retention feature to the body such that the at least one low-profile retention feature is configured to be movable between an open position and a closed position relative to the body, wherein:
in the open position, the at least one low-profile retention feature allows for insertion and removal of a component card into a connector of the riser card associated with the at least one low-profile retention feature; and
in the closed position, the at least one low-profile retention feature mechanically retains a top edge of a low-profile component card received into the riser card.

14. The method of claim 13, further comprising removably coupling the bracket to the body.

15. The method of claim 14, further comprising mechanically coupling the at least one low-profile retention feature to the bracket.

16. The method of claim 14, wherein the bracket is configured to mechanically retain respective tails of half-length component cards received into the riser card.

17. The method of claim 16, wherein removal of the bracket allows for insertion of a full-length component into a connector of the riser card corresponding to the removed bracket.

18. The method of claim 13, further comprising rotatably coupling a rotating riser cover to the body and configured to be movable between an open position and a closed position relative to the body, wherein:
in the open position, the rotating riser cover allows for insertion and removal of component cards into the riser card; and
in the closed position, the rotating riser cover mechanically retains a top edge of a full-height component card received into the riser card.
